(19) United States
(12) Patent Application Publication
(10) Pub. No.: US 2014/0069696 A1
(43) Pub. Date: Mar. 13, 2014

(54) METHODS AND APPARATUS FOR ATTACHING MULTI-LAYER FLEX CIRCUITS TO SUBSTRATES

(71) Applicant: APPLE INC., Cupertino, CA (US)

(72) Inventors: Fletcher R. Rothkopf, Mountain View, CA (US); Scott A. Myers, San Francisco, CA (US); Teodor Dabov, Mountain View, CA (US)

(73) Assignee: APPLE INC., Cupertino, CA (US)

(21) Appl. No.: 13/633,668

(22) Filed: Oct. 2, 2012

Related U.S. Application Data
(60) Provisional application No. 61/699,822, filed on Sep. 11, 2012.

(51) Int. Cl. H05K 1/02; H05K 3/36

(52) U.S. Cl. 174/254; 156/60

(57) ABSTRACT

Multi-layer ACF flex circuits can be bonded to multiple, separate and distinct circuits on substrates. The multi-layer ACF bonds are formed by aligning each of multiple circuits with a separate portion of a multi-layer ACF flex circuit and then forming ACF bonds using a single or multiple thermodes. The selection of single or multiple thermodes depends on the required thermal profile for each of the ACF bonds. The multiple ACF bonds may also be formed to a single multi-layer ACF flex circuit independently such that realignment may occur after individual bonds have already been formed.

### CROSS-REFERENCE TO RELATED APPLICATION

This application claims priority from U.S. Provisional Patent Application No. 61/699,822, filed Sep. 11, 2012, which is hereby incorporated by reference in its entirety.

### BACKGROUND

The explosion of the use of portable electronic devices, such as portable music players and mobile phones, has caused a continuous march toward ever thinner and lighter devices. This march is often a complicated balancing act between performance, battery life, weight and overall aesthetics.

One of the components that has come into increased use in portable electronic devices is anisotropic conductive film (ACF). ACF is a film that device manufacturers prefer to use because it is environmentally friendly (e.g., it is lead-free) and can be utilized to connect circuitry to the glass panels that are prevalent in these devices, as well as other substrates. For example, ACF bonding can also be used to connect flexible circuits to rigid circuit boards as well as to bond silicon chips to glass.

Many modern portable devices include a touch screen flat panel display that is made of glass or a similarly operating component. The display includes circuitry that must be interfaced with the rest of electronics in the devices. While conventional wires could be used, such wires are often impractical due to increased manufacturing requirements, as well as generally taking up significantly more room within the device. The use of ACF bonding for flex-on-glass, flex-on-board, flex-on-flex and other applications has become common place in the manufacturing of electronic devices.

Often, portable electronic devices have multiple, independent circuits therein. For example, the might be one circuit to control what appears on the display, and another circuit to control how touch inputs are received by the device. Each circuit is typically accompanied by a separate ACF flex circuit to attach that circuit from the glass to the device. The multitude of these flex circuits, however, take up precious space within the device and can severely limit the ability to make devices lighter and thinner. The use of multi-layer ACF interconnections, however, can replace several ACF films with a single film, thereby reducing the amount of space taken up within the device by ACF film. The one or more multi-layer ACF interconnects can be manufactured using different approaches.

### SUMMARY

Multi-layer ACF flex circuit interconnects and methods for making same are disclosed.

Multi-layer ACF flex circuit interconnects are manufactured that overcome limitations in traditional ACF bonding practice, such as when a multi-layer flex must be reduced to a single layer of conductor and a single layer of insulator. In that instance, the ACF bonding is applied to one of the sets of conductors, the opposite set is aligned and then heat and pressure is applied. By exposing multiple layers of conductors at the same time while and offsetting them, valuable real estate on the glass and within the device can be saved.

In some embodiments, for example, multiple glass substrates may be used, such as a piece of color filter glass and a thin film transistor (TFT) glass. Each piece of glass typically utilizes separate circuitry to control the functionality of that piece of glass. A single multi-layer flex circuit can be made having separate termination legs for each piece of glass. The two pieces of glass can be manufactured together, but physically offset from one another. In the region of the offset, a second set of termination contacts on the glass can be produced. The two independent sets of terminations could be bonded to their respective flex circuit in simultaneous heat/pressure processes, or they could be bonded in separate processes. For example, if the same or similar ACF material was being utilized in both terminations, a single simultaneous process of heat and pressure may be applied. On the other hand, if different ACF materials were used for each set of terminations, thereby calling for different heat/pressure profiles, each set of terminations can be bonded independently.

In other embodiments, the use of multi-layer ACF interconnections may be utilized to terminate different circuits on a single piece of glass or rigid printed circuit board by offsetting the location of the different sets of termination contacts on the same side of the glass. In still other embodiments, the use of multi-layer flexible printed circuits may be combined with multi-layer rigid printed circuit boards to provide higher density interconnects.

In still other embodiments, the use of multi-layer ACF interconnections can be used to provide an region of air-gap flex near the attachment points which can provide for independent alignment of the layers and which may be used to simplify the manufacturing processes. Other embodiments that may be employed can be utilized when, for example, a piece of double layer indium tin oxide (ITO) glass is used in a capacitive touch panel device. Under such circumstances, separate sets of conductors can be deposited on opposite surfaces of the glass which can then be terminated via separate pigtails from a single piece of multi-layer flex circuit during a single process of heat/pressure.

### BRIEF DESCRIPTION OF THE DRAWINGS

The above and other aspects and advantages of the invention will become more apparent upon consideration of the following detailed description, taken in conjunction with accompanying drawings, in which like reference characters refer to like parts throughout, and in which:

FIG. 1 is a cross-sectional view of a conventional flexible anisotropic conductive film (ACF);

FIG. 2 is a cross-sectional view of a portion of a conventional liquid crystal display (LCD);

FIG. 3 is a cross-sectional view of an ACF bonded to an LCD;

FIG. 4 is a cross-sectional view that shows part of a conventional process of bonding an ACF to an LCD;

FIG. 5 is a cross-sectional view of an LCD having an integrated touch panel;

FIG. 6 is a cross-sectional view of a multi-layer ACF that has been bonded to an integrated LCD/touch panel in accordance with some embodiments of the invention;

FIG. 7 is a cross-sectional view that shows part of a process of bonding a multi-layer ACF to an integrated LCD/touch panel in accordance with some embodiments of the invention;

FIG. 8 is a cross-sectional view that shows part of another process of bonding a multi-layer ACF to an integrated LCD/touch panel in accordance with some embodiments of the invention;

FIG. 9 is a cross-sectional view of a conventional multi-layer printed circuit board (PCB);

FIG. 10 is a cross-sectional view of a multi-layer ACF bonded to a multi-layer PCB in accordance with some embodiments of the invention;

FIG. 11 is a cross-sectional view of a multi-layer ACF having multiple bonds to the same surface of a rigid substrate in accordance with some embodiments of the invention;

FIG. 12 is a cross-sectional view of a multi-layer ACF bonded to a multi-layer PCB in accordance with some embodiments of the invention;

FIG. 13 is a cross-sectional view of a multi-layer ACF bonded to a multi-layer PCB in accordance with some embodiments of the invention;

FIG. 14 is a cross-sectional view of a multi-layer ACF bonded to a multi-layer PCB in accordance with some embodiments of the invention; and

FIG. 15 is a cross-sectional view of a multi-layer ACF bonded to a multi-layer PCB in accordance with some embodiments of the invention.

### DETAILED DESCRIPTION OF THE DISCLOSURE

Multi-layer anisotropic conductive films (ACF) bonded to substrates for use with portable electronic devices are disclosed. The multi-layer ACFs (or “flex circuits”) disclosed herein can be used for various purposes and in a variety of advantageous manners. For example, the multi-layer ACF bonding techniques disclosed herein could be utilized to reduce the number of flex circuits required in producing portable electronic devices, such as an iPhone™, an iPad™, or an iPod™, by Apple Inc. By reducing the number of required flex circuits, the overall dimensions of such products can be reduced in size, as well as a potential reduction in weight.

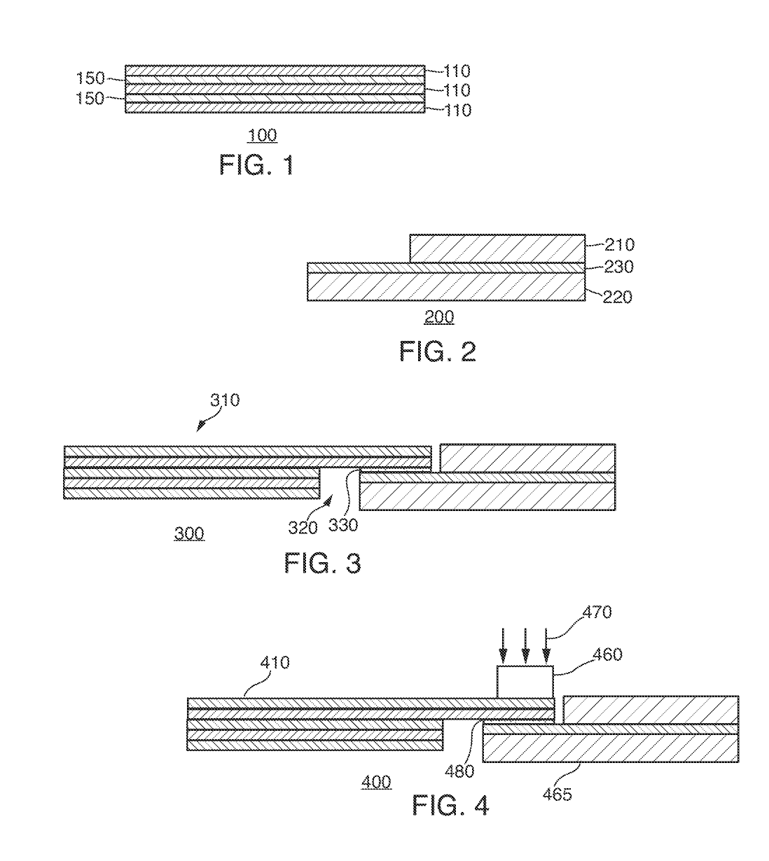

FIG. 1 generally shows a cross-sectional view of a conventional flex circuit 100. Flex circuit 100 includes three layers of insulator 110 (in the example shown in FIG. 1, that would include the top, bottom and middle layers), and two layers of conductive material 150, such as copper. Flex circuits are used for a variety of purposes and provide many advantages over individual wiring or ribbon cables. Flex circuits are thinner, taking up less weight and size, and are both flexible and durable. Flex circuits are typically utilized to connect different circuits together for operation. For example, a flex circuit could be used to connect a processor/control circuit to an LCD driver circuit that is fabricated on a glass substrate.

FIG. 2 generally shows a cross-sectional view of a portion of an active matrix LCD panel, in which a layer of thin film transistors is used to display images on the LCD. LCD panel 200 includes color filter glass 210 mounted to TFT glass 220, with a layer of thin film transistors 230 (or TFT layer 230) fabricated on TFT glass 220 (i.e., color filter glass 210 is mounted on top of TFT layer 230. The vast majority of liquid crystals displays in use today are fabricated as TFT LCD displays, due at least in part, to the ability to utilize color and ever higher resolutions than older LCD technologies. In order to operate the TFT layer, driver circuitry is typically fabricated on a portion of TFT glass 220. In order to control what is display on the LCD, the driver circuitry needs to be connected to the processing circuitry located in another part of the portable electronic device (not shown).

FIG. 3 shows an illustrative cross-sectional view of a portion of device 300 which includes flex circuit 310 bonded to the TFT layer of the LCD. As shown in FIG. 3, while flex circuit 310 is a multi-layer circuit, the portion that is bonded to the TFT layer is only a single layer of the multi-layer flex circuit. This can be seen in FIG. 3 at the location marked by reference numeral 320 (i.e., the empty space under the upper conductive layer of flex circuit 310). This is due to the limitation of conventional ACF bonding processes, as shown in FIG. 4.

FIG. 4 shows an illustrative cross-sectional view of a portion of a device 400 in which a conventional process for bonding one layer of a flex circuit to a substrate, such as a glass substrate, is utilized. Device 400 includes multi-layer flex circuit 410, which is being bonded to the TFT layer on top of TFT glass substrate 465. The ACF bonding material 480 forms a bond between the upper conductive layer of flex circuit 410 when pressure and heat are applied from thermode 460 in the direction shown by arrows 470. Thermode 460 applies both pressure and heat pressure for a predetermined amount of time which causes the ACF bonding material for form an ACF bond between the flex circuit and the TF layer of TFT glass 465.

In order for the ACF bond to be formed, however, the circuitry in multi-layer flex circuit 410 needs to be combined into a single layer for attachment to the TFT layer of TFT glass 465. If additional circuitry needs to be terminated on one or more portions of the LCD, additional flex circuits would be required to make the interconnection between the operational circuitry and the additional LCD connections.

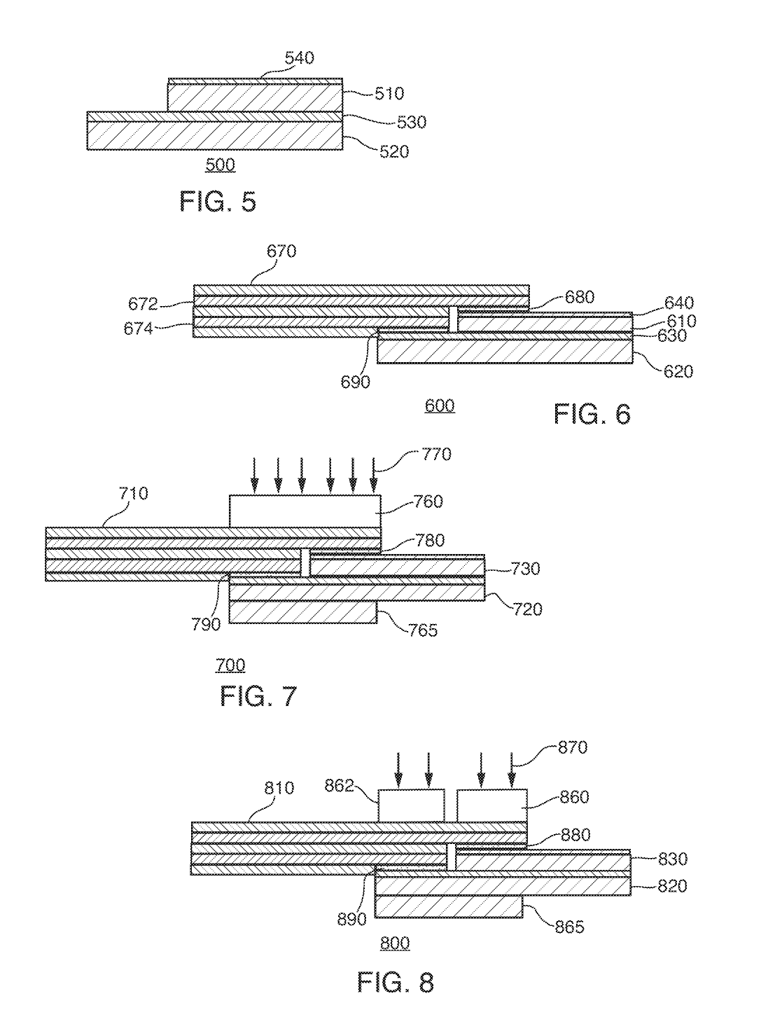

FIG. 5 shows an illustrative cross-sectional view of a liquid crystal display 500 which includes an integrated touch panel on the upper glass layer. LCD 500 includes color filer glass 510, TFT glass 520, TFT layer 530 and touch-sensitive layer 540. TFT layer 530 is located in between color filter glass 510 and TFT glass 520, while touch sensitive layer 540 is fabricated on the outer surface of color filter glass 510. LCD 500 is a device which requires two separate input from control circuitry in order to operate properly. TFT layer 530 includes a series of driver circuits that is operated from an LCD control circuit. Touch-sensitive layer 540, on the other hand, needs to be coupled to a different control circuit that can interpret touch-input commands as they are made by the user. If conventional ACF bonding processes were used, TFT layer 530 would be connected to its control circuitry via one flex circuit, and touch-sensitive layer 540 would be connected to its control circuitry through a second flex circuit.

FIG. 6 shows an illustrative cross-sectional view of a portion of device 600, in which a single multi-layer ACF flex circuit is bonded in multiple locations to glass substrates in accordance with some embodiments of the present invention. Device 600 includes color filter glass 610, TFT glass 620, TFT layer 630, touch-sensitive layer 640 and multi-layer flex circuit 670. Multi-layer 670 includes three layers of insulator/adhesive (i.e., the top, middle and bottom layers), and two conductive layers 672 and 674. Conductive layer 672 is ACF bonded to touch-sensitive layer 640 via ACF bond 680, while conductive layer 674 is ACF bonded to TFT layer 630 via ACF bond 690.

By utilizing some of the techniques in accordance with the present invention, a single multi-layer ACF flex circuit can be used to couple two different portions of the LCD to two different control circuits. For example, conductive layer 672 is bonded to touch-sensitive layer 640 at one end and to the control circuitry that evaluates touch-screen inputs commands at the other end (not shown). Conductive layer 674, on the other hand, is connected from TFT layer 630 to the control circuitry that provides control commands to the LCD drivers in order to control what is displayed by the LCD. The two different electrical connections from the LCD can be provided using a single flex circuit, thereby reducing the space and weight requirements of the supporting circuitry of device 600.

FIGS. 7 and 8 show two different processes for implementing multi-layer ACF bonding techniques of some of the embodiments of the present invention. FIG. 7 shows an illustrative cross-section view of one technique of multi-layer ACF bonding in accordance with the present invention in which the requirements of the two different bonds are either the same or are substantially the same. For example, if ACF bonding material 780 and ACF bonding material 790 are essentially the same, and the processing requirements are also essentially the same given that two different substrates are involved, then a single process can be utilized to form the ACF bonds in accordance with at least some embodiments of the present invention.

As shown in FIG. 7, device 700 includes multi-layer flex circuit 710, TFT glass 720, and color filter glass 730. TFT glass 720 includes a TFT layer as previously described (and as shown in FIG. 7), and color filter glass includes a touch-sensitive layer as previously described (and shown in FIG. 7). In device 700, two ACF bonds are formed simultaneously as ACF bonds 780 and 790. For ACF bonds 780 and 790 to be formed, multi-layer ACF flex circuit 710 has each of its two conductive layer aligned with a respective set of conductors on glasses 720 and 730. Once everything has been aligned, thermode 760 applies heat and pressure in the direction shown by arrows 770 which causes the bonding material to form into ACF bonds 780 and 790 (thermode 760 is countered by mechanical support 765 such that neither pieces of glass 720 and 730 are damaged when pressure is applied, and to enable pressure to be applied evenly).

FIG. 8, on the other hand, shows an illustrative cross-sectional view of an implementation of other embodiments of the present invention in which the two ACF bonds are formed separately. This may be required, for example, to insure that the proper thermal profile is used for each different bond. For example, the flex circuit bonded in ACF bond 880 may have a different thickness than the flex circuit bonded in ACF bond 890, and thus different process profiles could be required. Alternately, the ACF material used in each of ACF bonds 880 and 890 could be different such that they melt at different rates and different temperatures. In cases such as these, ACF bonding processes and techniques in accordance with some embodiments of the present invention may be utilized to process multiple different ACF bonds on a single multi-layer ACF flex circuit.

FIG. 8 shows a portion of a device 800 which includes ACF flex circuit 810, TFT glass substrate 820, and touch-sensitive glass 830. In this instance, the upper conductive layer of flex circuit 810 is aligned with the conductors for touch-sensitive layer that was fabricated on top of glass 830, while the lower conductive layer of flex circuit 810 is aligned with the conductors for the TFT layer fabricated on top of glass 820. Once everything is in the proper alignment, two different thermodes 860 and 862 are applied separately to form ACF bonds 880 and 890 (and thermodes 860 and 862 are supported by mechanical support 865). As described above, thermode 860 can utilize one thermal profile that can vary temperature, pressure, and or processing time (or any combination thereof), from the termal profile applied by thermode 862.

The multi-layer ACF bonding techniques shown and described in FIGS. 6-8 can be used on a wide range of applications, but may be particularly suited for applications where two different substrates need to be connected to two different circuits. For example, the use of “on-cell” capacitive touch sensors deposited on top of displays for use in multi-touch devices such as the iPhone, iPad and iPod Touch. In each of these instances, multiple layers of glass have electronic circuitry deposited on the surface, each of which needs to be connected to different control circuitry.

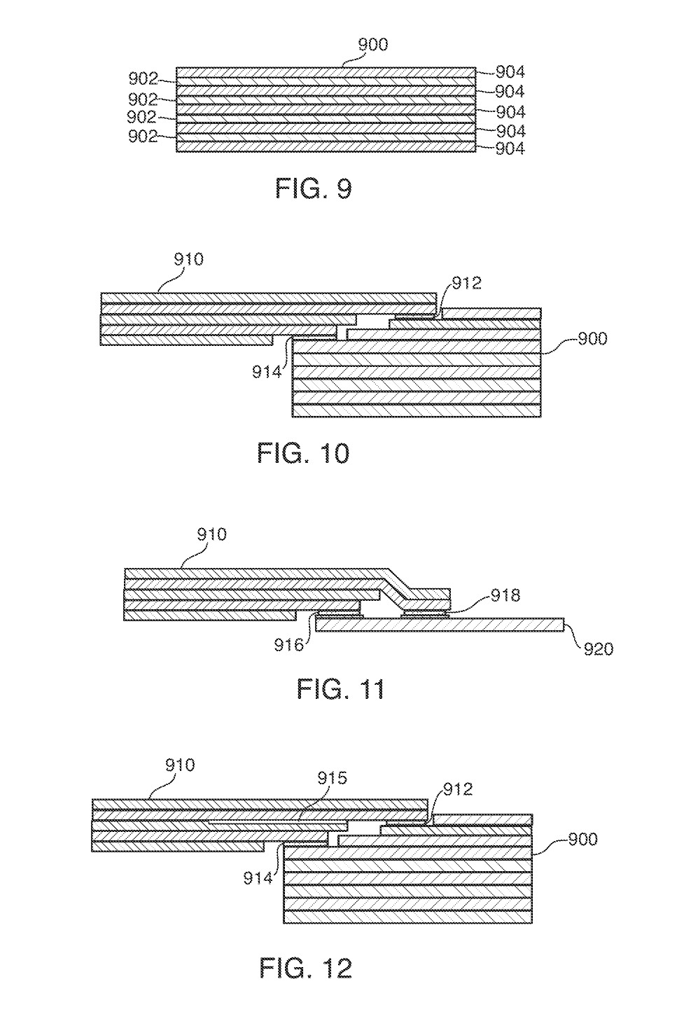

While the techniques described above have been focused thus far to glass substrates, the multi-layer ACF bonding techniques of some embodiments of the present invention may also be applied to multi-layer printed circuit board (PCB) applications. For example FIG. 9 shows an illustrative cross-section view of a printed circuit board 900, which includes four conductive layers 902, and five insulating layers 904. The techniques described herein for multi-layer ACF bonds can be utilized to interconnect various different layers of a multi-layer PCB to corresponding circuitry on a flex circuit.

FIG. 10 shows an illustrative cross-sectional view of a portion of a device in which two layers of multi-layer PCB 900 are connected to multi-layer ACF flex circuit 910. As shown, flex circuit 910 includes two conductive layers sandwiched between three insulating layers (as previously described). In this instance, the upper conductive layer of flex circuit 910 is ACF bonded to PCB 900 at bond 912, while the lower conductive layer of flex circuit 910 is bonded to PCB 900 at bond 914. Depending on the required thermal profiles, either of the techniques described above with respect to FIGS. 7 and 8 could be utilized. For example, if ACF bonds 912 and 914 have similar thermal profiles, a single thermode could be utilized such as thermode 760 in FIG. 7. On the other hand, if the thermal profiles of ACF bonds 912 and 914 vary, then thermodes 860 and 862 could be utilized.

FIG. 11 shows a cross-sectional view of other embodiments of the present invention in which multi-layer ACF flex circuitry is bonded to multiple locations of a single surface of a substrate, such as glass. FIG. 11 shows a portion of a device that includes multi-layer flex circuit 910 and glass substrate 920. In this instance, two different circuits have been deposited at two different locations on a single surface of glass 920 that need to be connected to different control circuits. As previously described, ACF bonds 916 and 918 can be formed by utilizing the techniques described above with respect to FIGS. 7 and 8 (depending on whether ACF bonds 916 and 918 have similar of varied thermal profiles).

FIG. 12 shows yet another application of some of the embodiments of the present invention in a cross-sectional view of a portion of a device having particular manufacturing requirements. In particular, the device shown in FIG. 12, which includes PCB 900 and multi-layer flex circuit 910, requires separate alignment prior to the forming of ACF bonds 912 and 914. In particular, the techniques of some embodiments of the present invention enable the use of flex circuit 910 having a modification such that an air gap 915 exists therein. As such, ACF bond 914 could be formed first, utilizing only thermode 862 (from FIG. 8). After ACF bond 914 was formed, airgap 915 would enable a realignment prior to the forming of ACF bond 912 using thermode 860 (from FIG. 8).

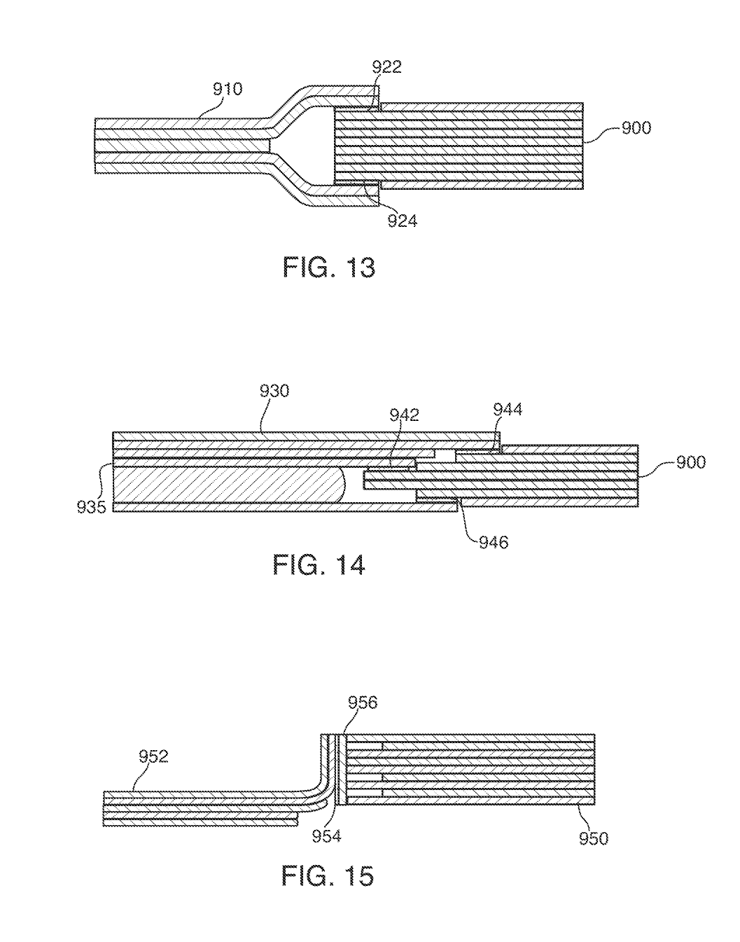

FIG. 13 shows an illustrative cross sectional view of a portion of a device in which the upper and lower conductive layers of PCB board 900 are ACF bonded to a multi-layer ACF flex circuit 910 in accordance with some embodiments of the present invention. In this instance, flex circuit 910 is split and PCB 900 is located between the conductive layers of flex circuit 910 such that ACF bonds 922 and 924 are formed. In this instance, two opposing thermodes similar to thermodes 860 and 862 would be utilized (and no mechanical support would be needed).

FIG. 14 shows an illustrative cross sectional view of a portion of a device in which coaxial shielding is utilized for a connection to PCB 900 in accordance with some embodiments of the present invention. In this instance, three different ACF bonds can be simultaneously formed at ACF bonds 942, 944 and 946 with multi-layer ACF flex circuit 930, such that conductor 935 is essentially a shielded trace with coaxial shielding. In this instance, various assembly techniques can be utilized in accordance with some embodiments of the present invention. For example, ACF bonds 942 and 944 could be formed as previously described (whereby a mechanical support could be utilized that also supports the formation of ACF bond 942. Once bonds 942 and 944 have been formed, alignment can then be performed prior to the formation of ACF bond 946 (similar to the techniques described above with respect to FIG. 12).

FIG. 15 shows an illustrative cross-sectional view of a device that includes PCB 950 and multi-layer ACF flex circuit 952. In this instance, PCB 950 includes a layer of plating 956 on the side of the PCB that makes contact with one of the conductive layers in the PCB. Using previously described techniques, flex circuit 952 can be ACF bonded to the plating to form ACF bond 954. In addition, other previously described techniques can also be used in combination with this technique to bond other portions of flex circuit 952 to other conductive layers of PCB 950.

The described embodiments of the invention are presented for the purpose of illustration and not of limitation.

What is claimed is:

1. A device comprising:
a multi-layer ACF flex circuit having at least first and second conductive elements;
a first substrate portion having a first set of electrical conductors;
a second substrate portion having a second set of electrical conductors;
a first ACF bond formed between the first conductive element and the first set of electrical conductors; and
a second ACF bond formed between the first conductive element and the first set of electrical conductors.

2. The device of claim 1, wherein the first substrate portion and the second substrate portion are each on different substrates.

3. The device of claim 1, wherein the first substrate portion and the second substrate portion are each on the same substrate.

4. The device of claim 1, wherein the first and second ACF bonds are formed simultaneously utilizing a single thermode.

5. The device of claim 1, wherein the first and second ACF bonds are each formed using different thermodes.

6. The device of claim 5, wherein the different thermodes are operated utilizing different thermal profiles to form the first and second ACF bonds.

7. The device of claim 1, wherein first substrate portion was fabricated on TFT glass.

8. The device of claim 7, wherein the second substrate portion was fabricated in connection with touch-sensitive glass.

9. The device of claim 8, wherein second substrate portion was fabricated in connection with “on-cell” capacitive touch sensors.

10. The device of claim 3, wherein the substrate is glass.

11. The device of claim 1, wherein the first and second substrate portions are first and second conductive layers of a printed circuit board.

12. The device of claim 12, wherein the first and second substrate portions are conductive layers that are adjacent to one another.

13. The device of claim 12, wherein the first and second substrate portions are the two conductive layers closest to each surface of the printed circuit board, and such that the printed circuit board is sandwiched between the first and second conductive elements of the ACF bonded flex circuit.

14. The device of claim 1, wherein the multi-layer flex circuit further comprises at least a third conductive element and the device further comprises:
a third substrate portion having a third set of electrical conductors; and
a third ACF bond formed between the third conductive element and the third substrate portion.

15. The device of claim 14, wherein the third ACF bond is formed such that it is a shielded trace located physically between the first and second ACF bonds.

16. The device of claim 11, wherein the printed circuit board comprises a side and one conductive layer of the printed circuit board extends to the side, the side being plated with electrically conductive material that makes electrical contact with the one conductive layer, the plated side comprising the first substrate portion.

17. A method for forming multi-layer ACF bonds between a multi-layer ACF flex circuit and at least first and second electrically conductive substrate portions comprising:
aligning a first flex circuit portion with the first electrically conductive portion;
depositing a first ACF bonding material to the location of alignment of the first flex circuit portion;
aligning a second flex circuit portion with the second electrically conductive portion;
depositing a second ACF bonding material to the location of alignment of the second flex circuit portion;
placing at least one thermode to the first and second locations of alignment; and
applying a combination of heat and pressure from the at least one thermode to form the first and second ACF bonds.

18. The method of claim 17, wherein the first and second bonding material is the same.

19. The method of claim 17, wherein the first and second bonding materials are different and the at least one thermode comprises two different thermodes.

20. The method of claim 17, wherein the first ACF bond is formed prior to the second ACF bond being formed, further comprising:
performing realignment prior to forming the second ACF bond.
